(19) United States
(12) Patent Application Publication
(10) Pub. No.: US 2004/0058526 A1
(43) Pub. Date: Mar. 25, 2004

(54) Via liner integration to avoid resistance shift and resist mechanical stress

(75) Inventors: Andrew Cowley, Hopewell Junction, NY (US); Michael Stetter, Munich (DE); Erdem Kaltalioglu, Wappingers Falls, NY (US); Mark Hoinkis, Fishkill, NY (US)

Correspondence Address: Frank Chau, F. CHAU & ASSOCIATES, LLP, Suite 501, 1900 Hempstead Turnpike, East Meadow, NY, 11554, US

(73) Assignee: Infineon Technologies North America Corp.

(21) Appl. No.: 10/253,941

(22) Filed: Sep. 24, 2002

(51) Int. Cl. H01L 21/44; H01L 21/4763

(52) U.S. Cl. 438/637; 438/679; 438/680

(57) ABSTRACT

Methods and devices are disclosed which provided lined conductive structures in semiconductor devices. Openings are formed in a dielectric layer to expose an underlying conductor. A first liner is deposited in the opening and on the underlying conductor by a physical vapor deposition process. A conformally deposited second liner is formed over the first liner, and a conductive structure is formed in the opening. Also, a sacrificial liner can be employed to getter undesirable compounds from the dielectric layer before forming a liner.

### BACKGROUND OF THE INVENTION

1. Field of the Invention

This disclosure relates to semiconductor fabrication, and more particularly, to a via liner and method that reduces resistance shift and withstands mechanical stress due to thermal cycling.

2. Discussion of Prior Art

Semiconductor devices employ metal layers for connecting electronic devices. Metal layers for semiconductors are electrically isolated from other metal layers and lines by employing dielectric layers there between. In one example, a dielectric layer is deposited on a semiconductor device and then is patterned to form trenches or holes therein. The trenches or holes can be filled with metal to provide interlevel connections or same level connections to various electrical components. These holes are referred to as vias and the metal filling the vias can be called contacts or in some cases vias.

Metal lines formed in such trenches typically include Aluminum. Aluminum is sufficient for many applications; however, other materials, such as copper, provide higher conductivity. Further, for logic applications, Aluminum may be unsuitable especially in smaller ground rule designs.

Higher conductivity is particularly useful in semiconductor devices with smaller line widths. As the line width decreases, resistance increases. Providing a material, like copper, which has a higher conductivity, may compensate for this.

Copper also has several shortcomings, however. For example, the dielectric layers employed for isolating copper can include oxygen. The electrical properties of copper degrade significantly when oxidized. Diffusion barriers employed between the dielectric layer and the copper, especially for smaller line widths, reduce the cross-sectional area of the copper in the trench since these diffusion barrier layers occupy space. Reduced line width due to diffusion barriers increases the resistance of the metal line for a given line width. These vias are especially vulnerable to resistance shifting due to thermal cycling caused by semiconductor chip processing or thermal cycling due to operation of the semiconductor device. Since thermal cycling also causes high shear stress through interconnect interfaces, such as through vias, connections between metal layers can be disrupted, broken or intermittent.

Back-end-of-line (BEOL) metallizations (upper metal layers) are particularly susceptible to resistance shift and mechanical stress due to thermal cycling. Therefore, a need exists for a method for increasing resistance to high shear stress and resistance shift due to thermal cycling.

### SUMMARY OF THE INVENTION

Methods and devices are disclosed which provide lined conductive structures in semiconductor devices. Openings are formed in a dielectric layer to expose an underlying conductor. A first liner is deposited in the opening and on the underlying conductor by a physical vapor deposition process. A conformally deposited second liner is formed over the first liner, and a conductive structure is formed in the opening. Also, a sacrificial liner can be employed to getter undesirable compounds from the dielectric layer before forming a liner.

These and other objects, features and advantages of the present invention will become apparent from the following detailed description of illustrative embodiments thereof, which is to be read in connection with the accompanying drawings.

### BRIEF DESCRIPTION OF THE DRAWINGS

This disclosure will present in detail the following description of preferred embodiments with reference to the following figures wherein:

FIG. 1 is a cross-sectional view of a semiconductor device is shown having a via formed in an interlevel dielectric layer in accordance with the present invention;

FIG. 2 is a cross-sectional view of the semiconductor device of FIG. 1 showing a via liner formed by a physical vapor deposition process in accordance with the present invention;

FIG. 3 is a cross-sectional view of the semiconductor device of FIG. 2 showing a second via liner formed by a conformal deposition process in accordance with the present invention;

FIG. 4 is a cross-sectional view of the semiconductor device of FIG. 3 showing a contact formed in accordance with the present invention;

FIG. 5 is a cross-sectional view of the semiconductor device of FIG. 4 showing a sacrificial layer formed in accordance with the present invention;

FIG. 6 is a cross-sectional view of the semiconductor device of FIG. 5 showing a via liner formed after the removal of the sacrificial layer in accordance with the present invention;

FIG. 7 is a cross-sectional view of the semiconductor device of FIG. 6 showing a contact formed in accordance with the present invention;

FIG. 8 is a cross-sectional view of a semiconductor device showing a dual damascene structure formed in accordance with the present invention; and

FIG. 9 is a cross-sectional view of a semiconductor device showing a dual damascene structure formed in accordance with the present invention.

### DETAILED DESCRIPTION OF PREFERRED EMBODIMENTS

The present invention provides an interface between a contact in a via and an interlevel dielectric layer. The interface provides increased mechanical strength to resist high shear stresses induced by thermal cycling. According to an embodiment of the present invention, a physically deposited layer can be provided as a liner before a conformal via liner is deposited. This physically deposited liner provides superior adhesion and reduces risk of shear stress failures. According to another embodiment of the present invention, a sacrificial liner can be deposited. The sacrificial layer can be employed as a gettering layer to remove undesirable compounds from the interlayer dielectric layer surrounding the via hole. The sacrificial layer can be removed at the via bottom and replaced at the top surface by a conformal via liner to provide superior adhesion to underlying Cu line.

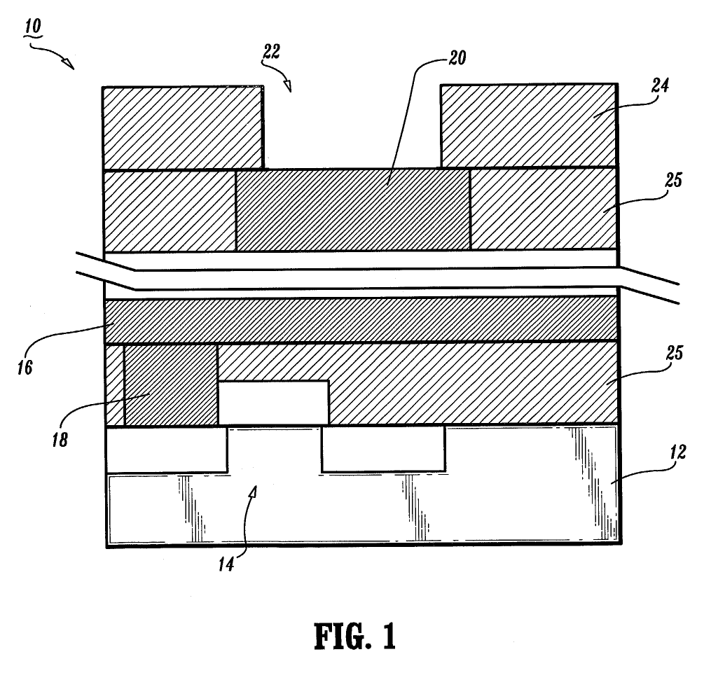

Referring now in specific detail to the drawings in which like reference numerals identify similar or identical elements throughout the several views, and initially to FIG. 1, a cross-sectional view of a partially fabricated semiconductor device 10 is shown. Device 10 can comprise a dynamic random access memory (DRAM), and static random access memory (SRAM), or any other device, which employs metallization levels. Device 10 comprises a substrate 12 having a plurality of devices 14 formed therein. Devices 14 are connected to metal layers 16 by interconnects or contacts 18.

FIG. 1 illustratively shows metal lines 20 extending into and out of the plane of the page. Metal lines 20 can comprise polysilicon, aluminum or copper. A via 22 can be formed in an interlevel dielectric layer 24. Interlevel dielectric layer 24 can comprise an inorganic layer, such as silicon oxide, or an organic dielectric material, such as SiLK® (Trademark of The Dow Chemical Company), or any other dielectric material. Other dielectric layers 25 are shown.

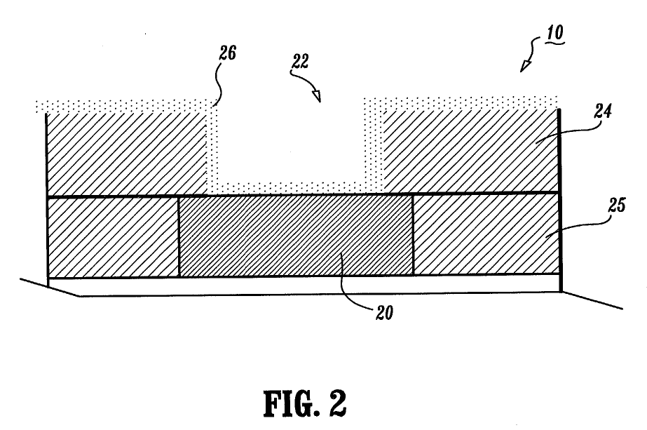

Referring to FIG. 2, a first liner layer 26 can be deposited in via 22. Liner 26 can be deposited by a physical vapor deposition (PVD) process or an ion PVD (IPVD) process, or chemical vapor deposition (CVD) process. Liner 26 can comprise TaN, TiN or Ta. Liner 26 can have a thickness of less than about 5 nm, preferably between 0.5 nm and 2 nm.

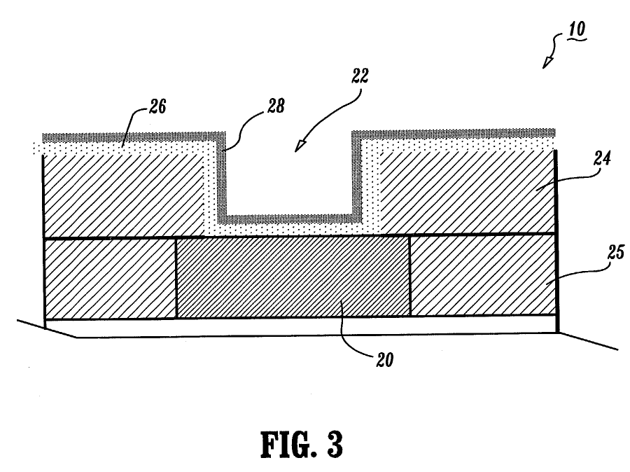

Referring to FIG. 3, a second liner layer 28 can be deposited over liner 26. Liner 28 conformally lines vias 22 over liner 26. Liner 28 can be deposited by a CVD process or PVD. Liner 28 can comprise TiN, Ta, TaN, W or other conformally deposited diffusion barrier materials. Liner 28 can be deposited to a thickness of less than or equal to 5 nm. Thicknesses of via liners 26 and 28 can be determined based on the line width of the via or metal lines, or based on other factors such as the alloys employed for interconnect contacts or metal lines. The present invention is particularly useful in sub-quarter micron ground rule technologies.

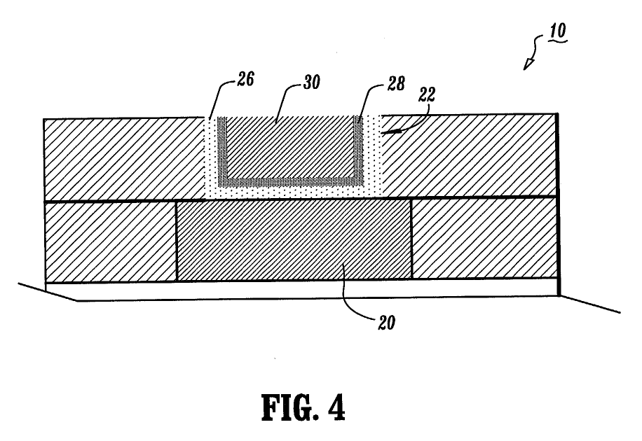

Referring to FIG. 4, a contact 30 can be deposited and a polishing process can be performed to contain contact 30 and liners 26 and 28 in via 22. Advantageously, the physical deposition process and conformal deposition process provide superior adhesion and hence mechanical strength between contact 30 and metal line 20. Contact 30 and metal line 20 preferably include copper, or its alloys, which provide superior conduction. The superior mechanical strength between contact 30 and metal line 20 provides a significant reduction in resistance shift due to thermal cycling, which can be a result of further processing, testing or operation of device 10.

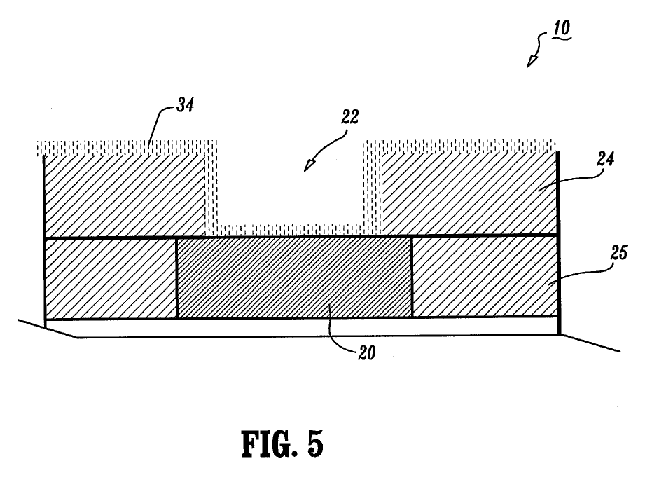

Referring to FIG. 5, another embodiment of the present invention is shown. A sacrificial layer 34 can be deposited in via 22 (e.g., shown in FIG. 1). Sacrificial layer 34 can be deposited by a PVD sputtering or a CVD process. Since layer 34 is a sacrificial layer, thicknesses of less than about 5 nm are preferable. Sacrificial layer 34 can comprise Ti, Ta or TaN or any other liner material. Removal of layer 34 can be performed by a sputter etching process using Argon etchants, or another etchant suitable to use, which removes sacrificial layer 34. The sacrificial layer can be removed completely or sputtered away only at via bottom and at surface for improved adhesion. Sacrificial layer 34 functions as a gettering layer and removes undesirable compounds, such as oxygen, nitrogen, carbon, etc. from interlevel dielectric layer 24, which preferably includes an organic dielectric material.

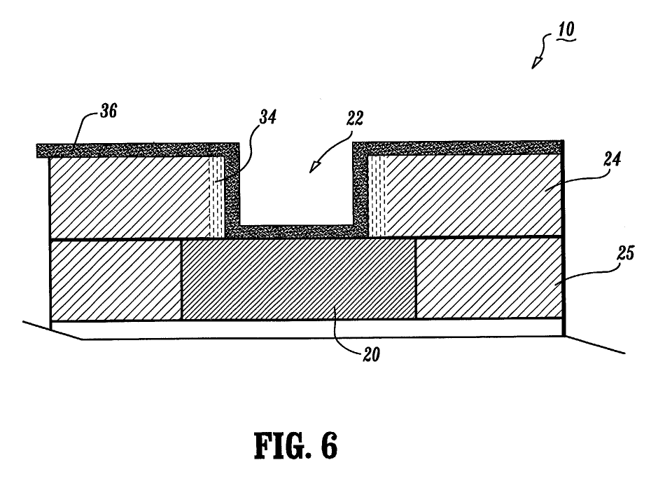

Referring to FIG. 6, a permanent liner 36 can be deposited after the removal of sacrificial layer 34. The sacrificial layer 34 can remain at the sidewalls. Liner 36 conformally lines via 22. Liner 36 can be deposited by a CVD process of PVD. Liner 36 comprises TiN, Ta, TaN, W or other conformally deposited diffusion barrier materials. Liner 36 can be deposited to a thickness of less than or equal to 5 nm. Thicknesses of via liner 36 can be determined based on the line width of the via or metal lines, or based on other factors such as the alloys employed for interconnect contacts or metal lines. The present invention is particularly useful in sub-quarter micron ground rule technologies.

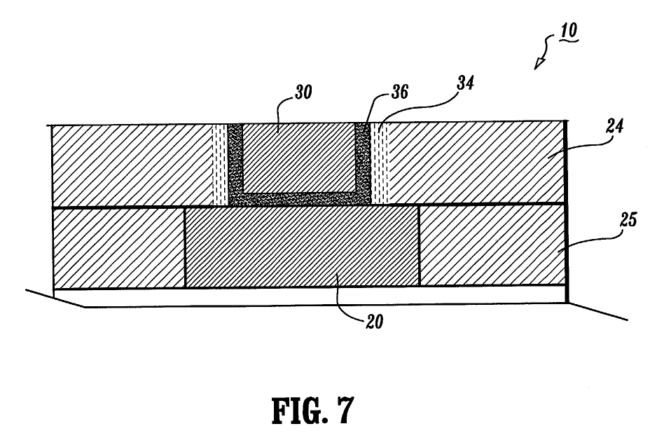

Referring to FIG. 7, a contact 30 can be deposited and a polishing process can be performed to contain contact 30, the remaining portions of the sacrificial layer and the liner 36 in via 22. Advantageously, the gettering process and conformal deposition process provide superior adhesion and hence mechanical strength between contact 30 and metal line 20. Contact 30 and metal line 20 preferably include copper, or its alloys, which provide superior conduction. The superior mechanical strength between contact 30 and metal line 20 provides a significant reduction in resistance shift due to thermal cycling, which can be a result of further processing, testing or operation of device 10.

The methods shown in FIGS. 1-7 can be applied to metal line trenches as well as for vias. It is to be understood that the embodiments as described above can be combined into a single process. For example, a sacrificial liner (34) can be deposited and removed. Then, first and second liners (26 and 28) are deposited in a via or metal line trench.

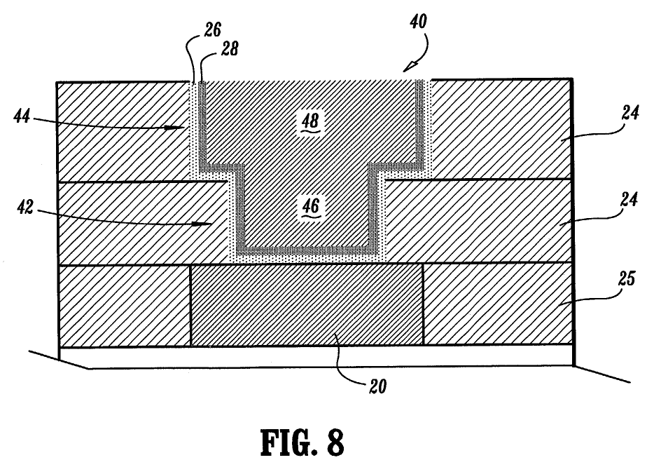

Referring to FIG. 8, a cross-sectional view of an example of a dual damascene structure 40 is shown. Structure 40 includes a via 42 and a metal line trench 44. Liners 26 and 28 are disposed along via 42 and trench 44 to provide superior mechanical adhesion between contact 46, metal line 48 and metal line 20.

In dual damascene structures, an inorganic etch stop layer can be provided between the via layer and the trench layer. An organic dielectric layer 24 can be used as the etch stop layer. Advantageously, no etch stop layer is needed between the dielectric layer for vias and the dielectric layer for metal line trenches. This is due to the mechanical robustness provided by the embodiments of the present invention.

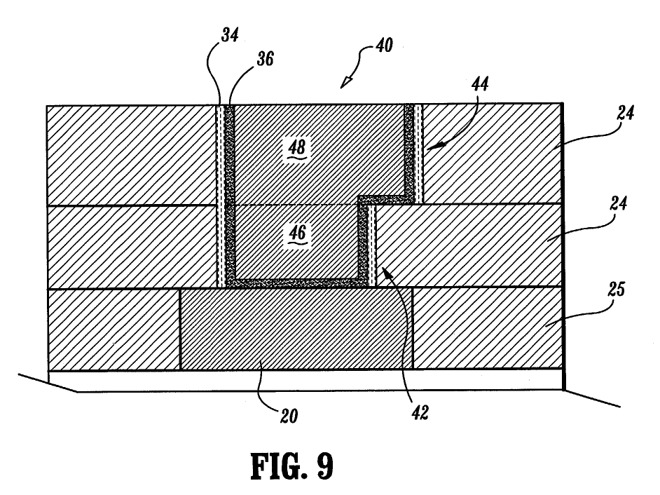

Referring to FIG. 9, a cross-sectional view of another example of a dual damascene structure 40 is shown. Structure 40 includes a via 42 and a metal line trench 44. The sacrificial layer 34 and liner 36 are disposed along via 42 and trench 44 to. provide superior mechanical adhesion between contact 46, metal line 48 and metal line 20.

Having described preferred embodiments for via liner integration to avoid resistance shift and resist mechanical stress (which are intended to be illustrative and not limiting), it is noted that modifications and variations can be made by persons skilled in the art in light of the above teachings. It is therefore to be understood that changes can be made in the particular embodiments of the invention disclosed which are within the scope and spirit of the invention as outlined by the appended claims. Having thus described the invention with the details and particularity required by the patent laws, what is claimed and desired protected by Letters Patent is set forth in the appended claims.

What is claimed is:

1. A method for lining conductive structures in semiconductor devices, comprising:
forming an opening in a dielectric layer to expose an underlying conductor;
depositing a first liner in the opening and on the underlying conductor by a physical vapor deposition process;
conformally depositing a second liner over the first liner; and
forming a conductive structure in the opening.

2. The method as recited in claim 1, wherein the conductive structure is one of a contact, a conductive line and a dual damascene structure.

3. The method as recited in claim 1, wherein the first liner comprises one of Ta, TaN, TiN, W, TiSiN.

4. The method as recited in claim 1, wherein the second liner comprises at least one of Ta, TaN, TiSiN and W.

5. The method as recited in claim 1, wherein the step of conformally depositing a second liner includes chemical vapor depositing the second liner.

6. The method as recited in claim 1, wherein the step of conformally depositing a second liner includes physical vapor depositing the second liner.

7. The method as recited in claim 1, wherein the dielectric layer comprises a dielectric material.

8. The method as recited in claim 1, wherein the conductive structure and the underlying conductor include copper.

9. A method for lining conductive structures in semiconductor devices, comprising:
forming an opening in a dielectric layer to expose an underlying conductor;
depositing a sacrificial liner in the opening to getter compounds from the dielectric layer;
removing the sacrificial liner; and
conformally depositing a second liner over the first liner; and
forming a conductive structure in the opening.

10. The method as recited in claim 9, wherein the conductive structure is one of a contact, a conductive line and a dual damascene structure.

11. The method as recited in claim 9, wherein the sacrificial liner includes one of Ta, TaN, TiN, W, TiSiN.

12. The method as recited in claim 9, wherein the second liner includes at least one of Ta, TaN, TiN, W, TiSiN.

13. The method as recited in claim 9, wherein the step of conformally depositing a second liner comprises one of physical vapor depositing the second liner and chemical vapor depositing the second liner.

14. The method as recited in claim 9, wherein the dielectric layer includes a dielectric material.

15. The method as recited in claim 9, wherein the conductive structure and the underlying conductor include copper.

16. A method for lining conductive structures in semiconductor devices, comprising:
forming an opening in a dielectric layer to expose an underlying conductor;
depositing a sacrificial liner in the opening to getter compounds from the dielectric layer;
removing the sacrificial liner;
depositing a first liner in the opening and on the underlying conductor by a physical vapor deposition process;
conformally depositing a second liner over the first liner; and
forming a conductive structure in the opening.

17. The method as recited in claim 16, wherein the conductive structure is one of a contact, a conductive line and a dual damascene structure.

18. The method as recited in claim 16, wherein the sacrificial liner comprises one of Ta, TaN, TiN, W, TiSiN.

20. The method as recited in claim 16, wherein the first liner comprises Ta, TaN, TiN, W, TiSiN.

21. The method as recited in claim 16, wherein the second liner comprises at least one of Ta, TaN, TiN, W, TiSiN.

22. The method as recited in claim 16, wherein the step of conformally depositing a second liner comprises one of chemical vapor depositing the second liner and physical vapor depositing the second liner.

23. The method as recited in claim 16, wherein the dielectric layer comprises a dielectric material.

24. The method as recited in claim 16, wherein the conductive structure and the underlying conductor include copper.

25. A semiconductor device, comprising:
a dielectric layer patterned to form an opening in communication with an underlying conductor;
a physical vapor deposited first liner formed over walls of the opening and on the underlying conductor by a process;
a conformally deposited second liner formed over the first liner; and
a conductive structure formed on the second liner in the opening to provided electrical contact with the underlying conductor.

26. The device as recited in claim 25, wherein the conductive structure comprises one of a contact, a conductive line and a dual damascene structure.

27. The device as recited in claim 25, wherein the first liner comprises Ta, TaN, TiN, W, TiSiN.

28. The device as recited in claim 25, wherein the second liner comprises at least one of Ta, TaN, TiN, W, TiSiN.

29. The device as recited in claim 25, wherein the dielectric layer comprises a dielectric material.

30. The method as recited in claim 25, wherein the conductive structure and the underlying conductor include copper.
